(19) United States
(12) Patent Application Publication
(10) Pub. No.: US 2025/0285960 A1
(43) Pub. Date: Sep. 11, 2025

(54) SEMICONDUCTOR DEVICES HAVING A PATTERNED CONTACT

(71) Applicant: TAIWAN SEMICONDUCTOR MANUFACTURING COMPANY LTD., HSINCHU (TW)

(72) Inventors: JIA-HONG GAO, HSINCHU COUNTY (TW); HUI-ZHONG ZHUANG, KAOHSIUNG CITY (TW); GUO-HUEI WU, TAINAN CITY (TW)

(21) Appl. No.: 18/597,966

(22) Filed: Mar. 7, 2024

(51) Int. Cl. H01L 23/522; H01L 23/528; H01L 29/66

(52) U.S. Cl. CPC H01L 23/5226; H01L 23/5283; H10D 64/017

(57) ABSTRACT

The present disclosure provides semiconductor devices. The semiconductor device comprises a substrate having a first surface and a second surface opposite to the first surface, one or more dummy gate segments disposed on the first surface of the substrate and extend in parallel, a first contact on the first surface of the substrate, a backside conductive via penetrating from the second surface to the first surface of the substrate, and connected to the first contact, a first conductive segment and a second conductive segment disposed on and extending perpendicular to the one or more dummy gate segments. The first contact across at least one of the dummy gate segments, and is connected to the first conductive segment and the second conductive segment.

### TECHNICAL FIELD

The present disclosure relates in general to semiconductor devices. Specifically, the present disclosure relates to semiconductor devices having patterned source/drain contacts.

### BACKGROUND

Currently, power cells in which feed through via (FTV) penetrates the substrate and connects elements on opposite sides of the substrate have been proposed. In current power cells, FTV connects the backside metal segments to a single metal segment on the front side of the substrate through a contact. With only one metal segment establishing the conductive path, high resistance to power delivery remains. Therefore, a special pattern for the contact on the front side of the substrate to enhance connection and contact area for optimal resistance is called for.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a schematic layout diagram of a semiconductor device, in accordance with some embodiments of the present disclosure.

FIG. 1A is a top view of a semiconductor device, in accordance with some embodiments of the present disclosure.

FIG. 1B is a cross-section of a semiconductor device along line 1B-1B of FIG. 1A, in accordance with some embodiments of the present disclosure.

FIG. 1C is a cross-section of a semiconductor device along line 1C-1C of FIG. 1A, in accordance with some embodiments of the present disclosure.

FIG. 2 is a schematic layout diagram of a semiconductor device, in accordance with some embodiments of the present disclosure.

FIG. 2A is a top view of a semiconductor device, in accordance with some embodiments of the present disclosure.

FIG. 2B is a cross-section of a semiconductor device along line 2B-2B of FIG. 2A, in accordance with some embodiments of the present disclosure.

FIG. 2C is a cross-section of a semiconductor device along line 2C-2C of FIG. 2A, in accordance with some embodiments of the present disclosure.

FIG. 2D is a cross-section of a semiconductor device along line 2D-2D of FIG. 2A in accordance with some embodiments of the present disclosure.

FIG. 3A is a top view of a contact of a semiconductor device, in accordance with some embodiments of the present disclosure.

FIG. 3B is a top view of a contact of a semiconductor device, in accordance with some embodiments of the present disclosure.

FIG. 4A is a schematic layout diagram of a semiconductor device, in accordance with some embodiments of the present disclosure.

FIG. 4B is a schematic layout diagram of a semiconductor device, in accordance with some embodiments of the present disclosure.

FIG. 5A is a schematic layout diagram of a semiconductor device, in accordance with some embodiments of the present disclosure.

FIG. 5B is a schematic layout diagram of a semiconductor device, in accordance with some embodiments of the present disclosure.

FIG. 6 is a block diagram of an IC layout diagram generation system, in accordance with some embodiments.

FIG. 7 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

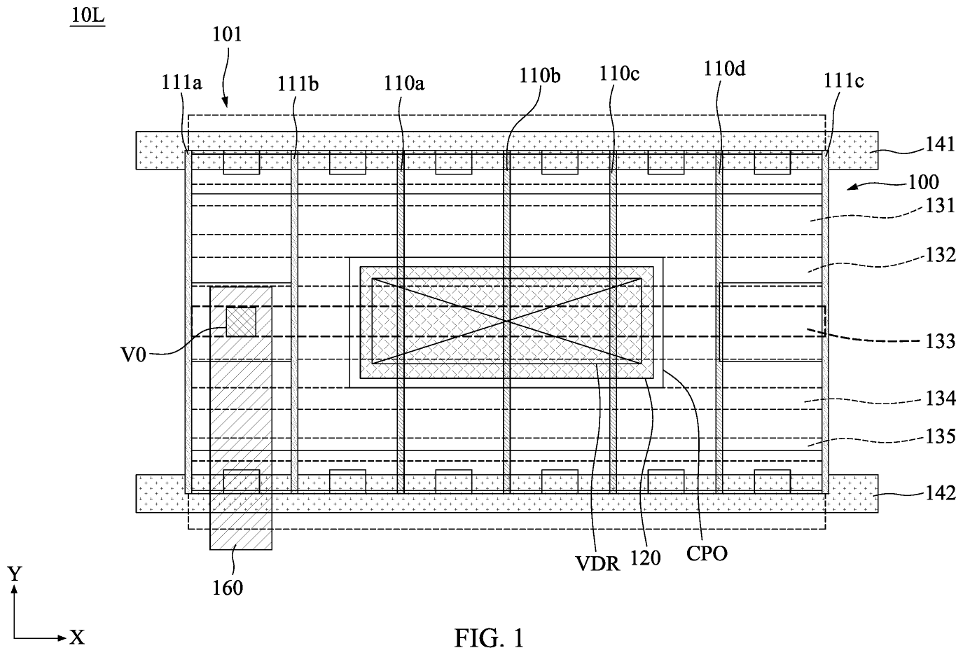

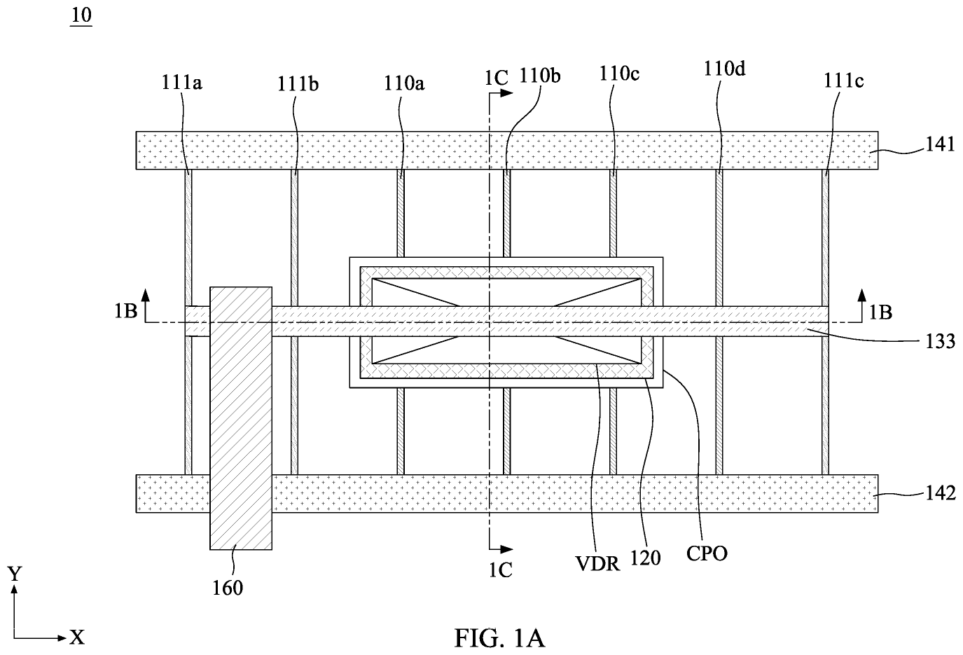

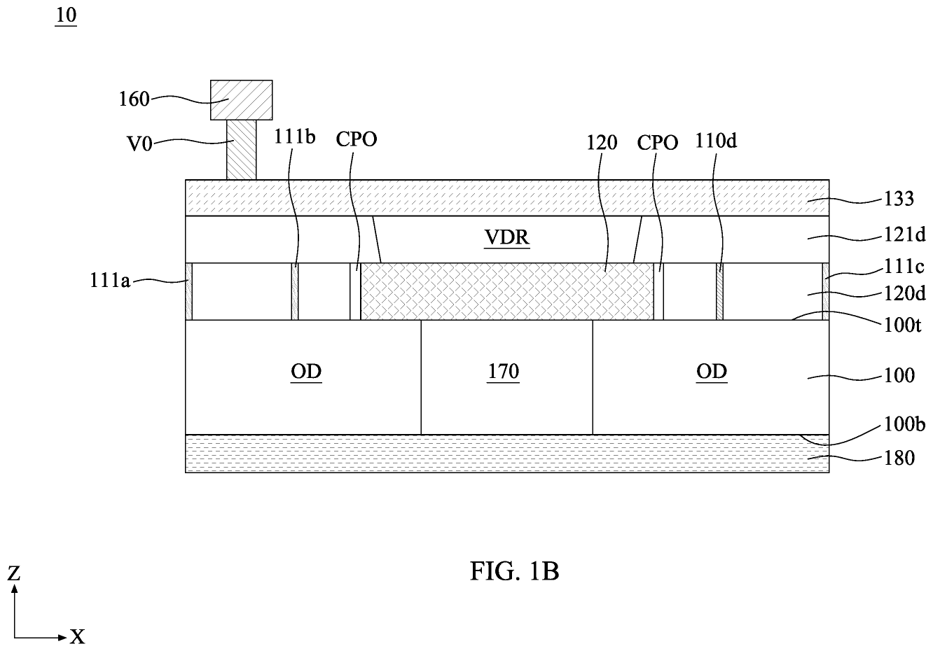

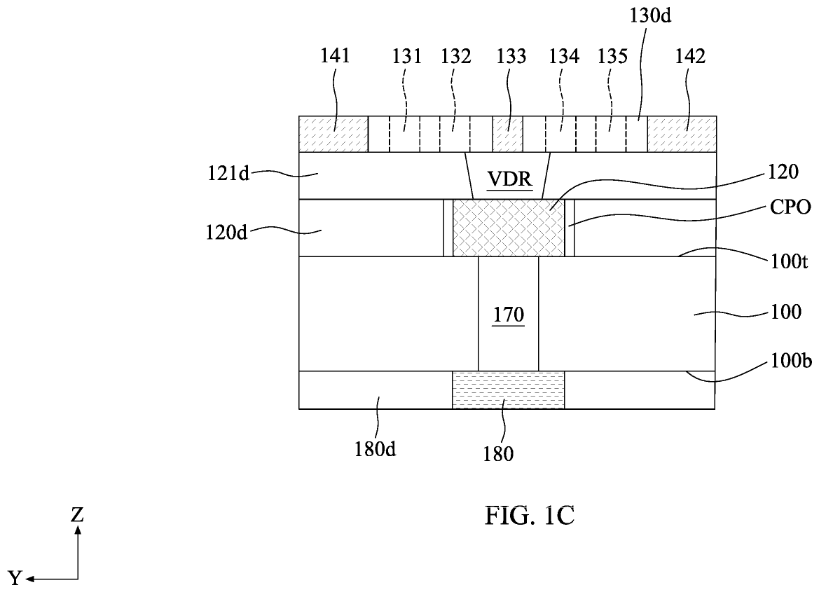

FIG. 1 is a schematic layout diagram 10L of a semiconductor device 10, in accordance with some embodiments of the present disclosure.

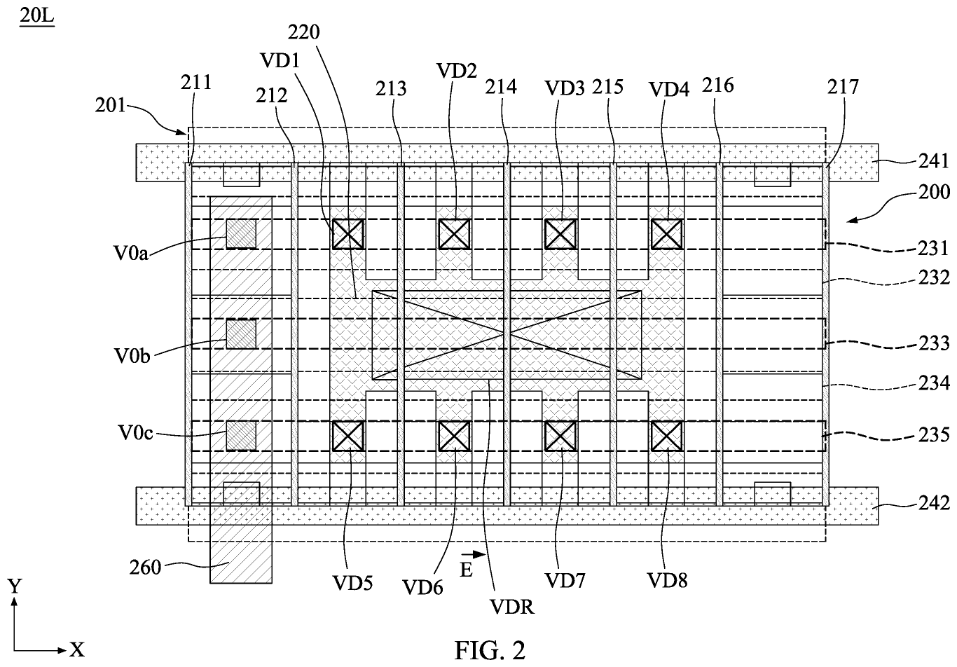

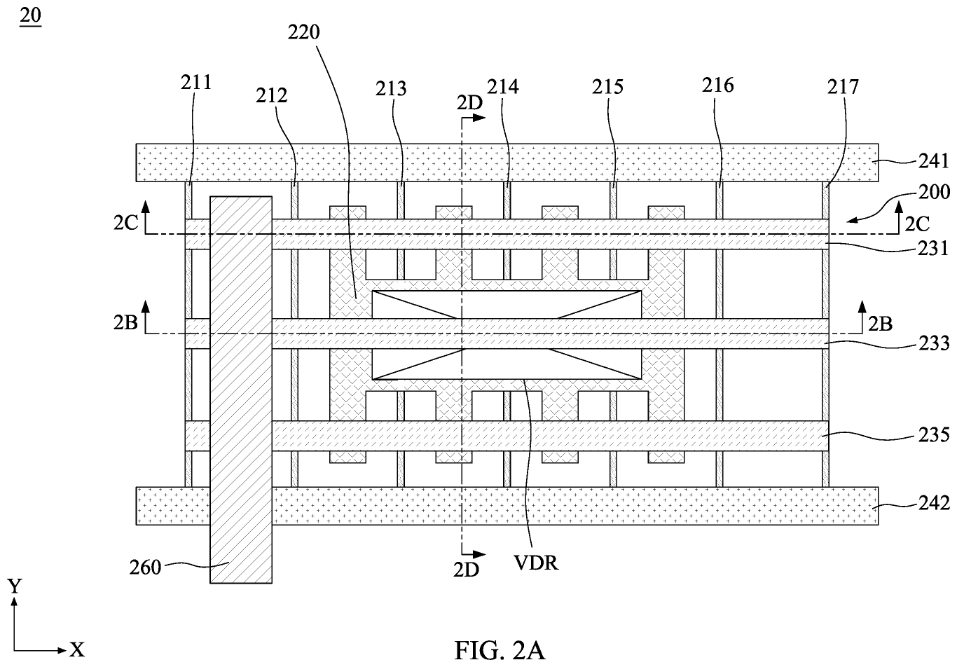

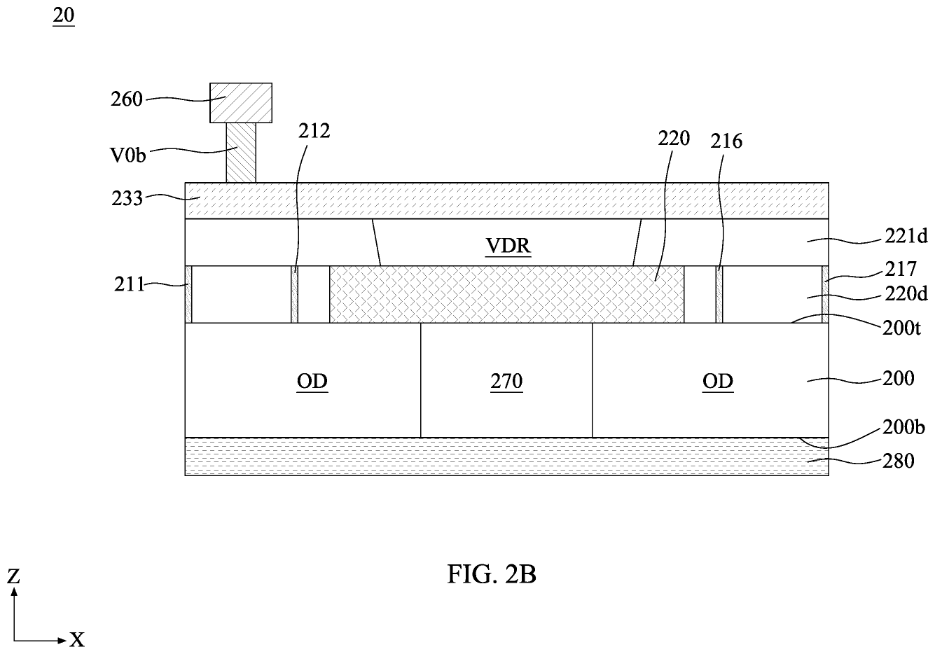

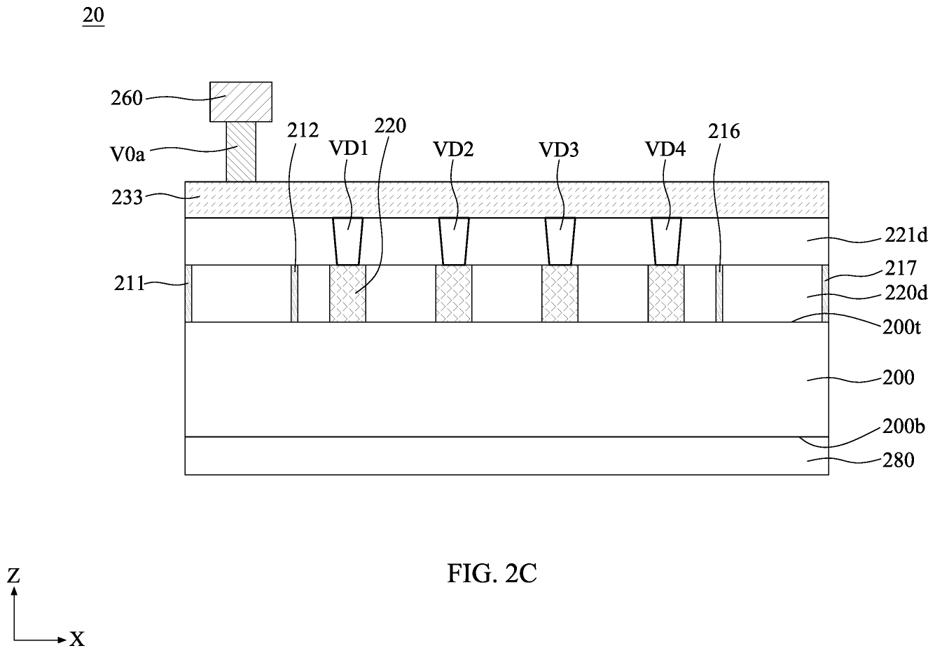

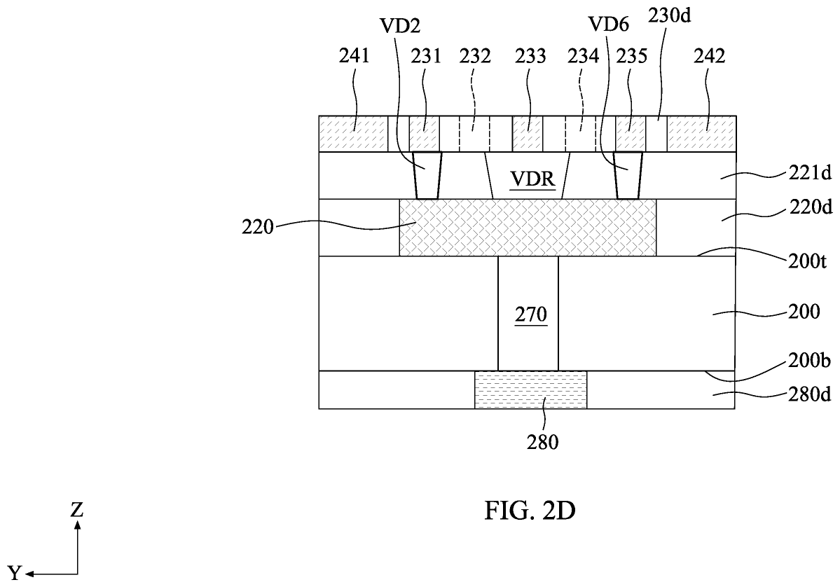

In general, a layout diagram represents a semiconductor device. Shapes in the layout diagram represent corresponding components in the semiconductor device. The layout diagram per se is a top view. Shapes in the layout diagram are two-dimensional relative to, e.g., the X-axis and the Y-axis, whereas the semiconductor device being represented is three-dimensional. Typically, relative to the Z-axis, the semiconductor device is organized as a stack of layers in which are located corresponding structures, i.e., to which belong corresponding structures. Accordingly, each shape in the layout diagram represents, more particularly, a component in a corresponding layer of the corresponding semiconductor device. Typically, the layout diagram represents relative depth, i.e., positions along the Z-axis, of shapes and thus layers by superimposing a second shape on a first shape so that the second shape at least partially overlaps the first shape. For simplicity of discussion, i.e., as a discussion-expedient, some elements in layout diagram (e.g., FIGS. 1, 2 and the other layout diagrams disclosed herein) are referred to as if they are counterpart structures in a corresponding semiconductor device rather than patterns/shapes per se.

Referring to FIG. 1, the semiconductor device 10 can include a substrate 100 (shown in FIG. 1B), four gate segments 110a, 111b, 110c, and 110d, three dummy gate segments 111a, 111b, and 111c, a cutting region CPO, a contact 120, a conductive via VDR, five conductive segments 131, 132, 133, 134, and 135, power rails 141 and 142, a conductive via V0, and a conductive segment 160. The semiconductor device 10 may include a power cell 101. The power cell 101 may include a feed through via (FTV) penetrating the substrate 100 and electrically connecting conductive traces on the opposite sides on the substrate 100. In some embodiments, the FTV may carry the power supply signals. Details of the FTV are discussed in FIGS. 1B and 1C.

The substrate 100 can include one or more active regions (OD) and isolation structures (STI) (not shown). The active regions may also be referred to as oxide diffusions or oxide dimensioned areas. In some embodiments, the active region (OD) can be defined and laterally surrounded by isolation structures (STI). The active region (OD) and the isolation structures (STI) may be disposed in the same layer. In some embodiments, each of the active regions (OD) may include two source/drain regions and a channel region of a transistor (not shown) interposed between the two source/drain regions. The gate segments may be disposed on the channel region of the transistor to form the gate of the transistor. The source/drain regions in the active region (OD) can be N-type active regions doped with N-type impurities such as arsenic, phosphorus, or the like, or P-type active regions doped with P-type impurities such as boron or the like. The channel region in the active region (OD) may be undoped or lightly doped. In some embodiments, the isolation structures (STI) are formed of dielectric materials, such as oxide or nitride, and may be referred to as shallow trench isolation.

In some embodiments, the gate segments 110a, 110b, 110c, and 110d and the dummy gate segments 111a, 111b, and 111c can be disposed on the substrate 100 and extend vertically from a top view. The gate segments 110a, 110b, 110c, and 110d and the dummy gate segments 111a, 111b, and 111c may be disposed on the active regions (OD) of the substrate 100.

The gate segments 110a, 110b, 110c, and 110d and the dummy gate segments 111a, 111b, and 111c may be distributed evenly. That is, the distance between the dummy gate segments 111a and 111b may be substantially identical to that between the dummy gate segment 111b and the gate segment 110a. The distance between the dummy gate segment 111b and the gate segment 110a may be substantially identical to that between the gate segments 110a and 110b. The distance between the gate segments 110a and 110b may be substantially identical to that between the gate segments 110b and 110c. The distance between the gate segments 110b and 110c may be substantially identical to that between the gate segments 110c and 110d. The distance between the gate segments 110c and 110d may be substantially identical to that between the gate segment 110d and the dummy gate segment 111c.

The gate segments 110a, 110b, 110c, and 110d may be formed of a conductive material, such as doped polysilicon. In some embodiments, the gate segments 110a, 110b, 110c, and 110d can be formed of metallic materials such as tungsten, cobalt, and other work function adjusting metals, such as Ti, Al, TiAl, TIN, TaC and the like. Although not explicitly shown in FIG. 1, a gate dielectric film formed of dielectric materials may be arranged between the channel region and the gate segments 110a, 110b, 110c, and 110d. In some embodiments, the dummy gate segments 111a, 111b, and 111c may be formed of insulation materials.

In some embodiments, the number of segments 110a to 110d and 111a to 111c (including gate segments and dummy gate segments) can be more or less than seven according to need. The type (gate segment or dummy gate segment) of segments may be determined according to need. In some embodiments, the segments 110a to 110d and 111a to 111c can be all gate segments, or all dummy gate segments.

In some embodiments, the cutting region CPO may be disposed on the substrate 100. The cutting region CPO may separate the gate segment (such as gate segments 110a, 110b, and 110c). For example, the gate segment 110a can be separated by the cutting region CPO into two segments. In some embodiments, the cutting region CPO can be large enough to cut one or more of the gate segments 110a, 110b, and 110c.

The cutting region CPO may be formed by removing a portion of the gate segments and the surrounding dielectric material, and then inserting insulation material. In other words, the cutting region CPO includes insulation materials. The cutting region CPO may be rectangular. In some embodiments, the cutting region CPO may extend substantially perpendicular to the gate segments 110a, 110b, and 110c. The cutting region CPO may extend horizontally. In some embodiments, the cutting region CPO may provide a keep-out zone for the FTV, such that the penetration of the FTV does not impact the gate segments 110a, 110b, and 110c, and the connection between conductive traces on opposite sides of the substrate 100 can be established.

The contact 120 can be disposed on the substrate 100. In some embodiments, the contact 120 may be disposed adjacent to the gate segments 110a, 110b, and 110c. In some embodiments, the contact 120 is located in a layer identical to that of the gate segments 110a, 110b, and 110c. The contact 120 may be rectangular. In some embodiments, the contact 120 may extend substantially perpendicular to the gate segments 110a, 110b, and 110c. The contact 120 may extend horizontally from a top view perspective. The contact 120 may be across at least one of the gate segments 110a, 110b, and 110c. In some embodiments, the contact 120 can be across three gate segments 110a, 110b, and 110c.

The contact 120 may be disposed within the cutting region CPO. The contact 120 does not overlap the gate segments 110a, 110b, and 110c from a top view, since the gate segments 110a, 110b, and 110c are cut by the cutting region CPO. The size of the contact 120 can be less than the size of the cutting region CPO. For example, the length and width of the contact 120 can be less than the length and width of the cutting region CPO. In other words, the contact 120 can be completely within the cutting region CPO. In some embodiments, the contact 120 can be connected to the FTV (see FIGS. 1B and 1C). The contact 120 may be formed of conductive materials, such as copper, tungsten, aluminum, titanium, tantalum, alloys thereof, or the like.

Referring to FIG. 1, the semiconductor device 10 can include five conductive segments 131, 132, 133, 134, and 135. The conductive segments 131, 132, 133, 134, and 135 are disposed on the gate segments 110a, 110b, 110c, and 110d. The conductive segments 131, 132, 133, 134, and 135 are disposed on the contact 120. In some embodiments, the conductive segments 131, 132, 133, 134, and 135 can be disposed on the active regions of the substrate 100. The conductive segments 131, 132, 133, 134, and 135 can extend perpendicular to the gate segments 110a, 110b, 110c, and 110d. That is, the conductive segments 131, 132, 133, 134, and 135 can extend horizontally from a top view.

In some embodiments, the conductive segments 131, 132, 133, 134, and 135 are allocated into tracks for the power cell 101, throughout the present disclosure, the term “track” is defined as predetermined regions of the power cell 101 from a top-view perspective in which conductive segments or power rails can be located. In some embodiments, the track is in a strip or line profile. The number of parallel tracks and the track pitch can be predetermined in order to fulfill design rules. In some embodiments, the conductive segments 131, 132, 133, 134, and 135 can be patterned in their own tracks. For clarity, FIG. 1 shows the track of merely conductive segments 131, 132, 133, 134, and 135 rather than the detailed pattern.

The power rails 141 and 142 are arranged in the same layer as the conductive segments 131, 132, 133, 134, and 135. The power rails 141 and 142 extend parallel to the conductive segments 131, 132, 133, 134, and 135. The power rails 141 and 142 are on opposite sides of the power cell 101. For example, the power rails 141 and 142 can be arranged on an upper cell side and a lower cell side, respectively, of the power cell 101. In some embodiments, the power rails 141 and 142 can be configured to supply a voltage VDD and a voltage VSS, respectively. In some embodiments, the voltage VDD can be a positive voltage and the voltage VSS can be ground.

In some embodiments, a width of the power rails 141 and 142 along a vertical orientation substantially exceeds that of the conductive segments 131, 132, 133, 134, and 135 along a vertical orientation. In other embodiments, the power rails 141 and 142 and the conductive segments 131, 132, 133, 134, and 135 can have substantially equal widths along a vertical orientation. In some embodiments, the conductive segments 131, 132, 133, 134, and 135 are equally spaced between the power rails 141 and 142 along a vertical orientation. In addition, the power rail 141 is spaced from its adjacent conductive segment 131 by a distance along a vertical orientation, and the power rail 142 is spaced from its adjacent conductive segment 135 by a distance along a vertical orientation.

The conductive segments 131, 132, 133, 134, and 135, and the power rails 141 and 142 may be formed of conductive materials, such as copper, tungsten, aluminum, titanium, tantalum, alloys thereof, or the like.

In some embodiments, a conductive via VDR can be disposed on the contact 120. The conductive via VDR may be disposed between the contact 120 and the conductive segment 133. The conductive via VDR can electrically connect the contact 120 and the conductive segment 133.

The size of the conductive via VDR can be less than the size of the contact 120. For example, the length and width of the conductive via VDR can be less than the length and width of the contact 120. In other words, the conductive via VDR can be completely within the contact 120. In some embodiments, the conductive via VDR may be larger than other normal conductive vias in the same layer to enable transmission of power signals with relatively lower resistance. The conductive via VDR can be wider than the conductive segment 133 along the vertical orientation. The conductive via VDR can be across the gate segments 110a, 110b, and 110c. The conductive via VDR may be formed of conductive materials, such as copper, tungsten, aluminum, titanium, tantalum, alloys thereof, or the like.

In some embodiments, the conductive segment 160 can be disposed on the conductive segments 131, 132, 133, 134, and 135. The conductive segment 160 is disposed between the dummy gate segments 111a and 111b. In some embodiments, the conductive segment 160 can be disposed on the active regions of the substrate 100. The conductive segment 160 can extend parallel to the dummy gate segments 111a, 111b, and 111c. That is, the conductive segment 160 can extend vertically from a top view. In some embodiments, the conductive segments 160 and 133 can partially overlap from a top view. The conductive segment 160 may extend beyond the power cell 101 so as to connect to other cells. The conductive segment 160 may be formed of conductive materials, such as copper, tungsten, aluminum, titanium, tantalum, alloys thereof, or the like.

In some embodiments, a conductive via V0 can be disposed on the conductive segment 133. The conductive via V0 may be disposed between the conductive segments 133 and 160. The conductive via V0 can electrically connect the conductive segments 133 and 160. In some embodiments, the conductive via V0 can overlap the conductive segments 133 and 160 from a top view. The conductive via V0 may be formed of conductive materials, such as copper, tungsten, aluminum, titanium, tantalum, alloys thereof, or the like.

FIG. 1A is a top view of a semiconductor device, in accordance with some embodiments of the present disclosure. FIG. 1A is a top view of a semiconductor device 10, manufactured in accordance the schematic layout diagram 10L of FIG. 1. Some shapes shown in the layout diagram 10L will not exist in the semiconductor device 10. For example, the semiconductor device 10 may not include the cell boundary of the power cell 101, the tracks of the conductive segments 131, 132, 134, and 135, and the portion of the gate segments 110a, 110b, and 110c that is cut by the cutting region CPO. In some embodiments, the conductive via V0 is not shown in FIG. 1A since it is covered by the conductive segment 160. In some embodiments, the semiconductor device 10 may merely include the conductive segment 133, and there may be no conductive material formed in the track of the conductive segments 131, 132, 133, and 135. In another embodiments, the semiconductor device 10 may include the conductive segment 133 and a part of the conductive segments 131, 132, 133, and 135 (not shown).

FIG. 1B is a cross-section of a semiconductor device 10 along line 1B-1B of FIG. 1A, in accordance with some embodiments of the present disclosure. Referring to FIG. 1B, the substrate 100 may have a top surface 100t and a bottom surface 100b. In some embodiments, the FTV 170 may penetrate the substrate 100. The FTV 170 may taper from the bottom surface 100b to the top surface 100t (not shown). In another embodiment, the FTV 170 may taper from the top surface 100t to the bottom surface 100b (not shown). In some embodiments, the FTV 170 may have a substantially uniform width or diameter. In some embodiments, the FTV 170 may be referred to as a backside conductive via. The FTV 170 may be a conductive pillar. The FTV 170 may be formed of conductive materials, such as copper, tungsten, aluminum, titanium, tantalum, alloys thereof, or the like.

In some embodiments, one or more backside conductive segments 180 can be disposed on the bottom surface 100b of the substrate 100. The backside conductive segments 180 can be patterned. In some embodiments, the backside conductive segments 180 may extend parallel to the conductive segments 131, 132, 133, 134, and 135. The backside conductive segments 180 may be formed of conductive materials, such as copper, tungsten, aluminum, titanium, tantalum, alloys thereof, or the like.

The contact 120 can be disposed on the top surface 100t of the substrate 100, and surrounded by the cutting region CPO. The contact 120 is wider than the FTV 170. In some embodiments, the contact 120 and the backside conductive segment 180 are disposed on opposite surfaces of the substrate 100 and connected through the FTV 170.

The gate segment 110d and dummy gate segments 111a, 111b, and 111c are disposed on the top surface 100t of the substrate 100. The gate segment 110d and dummy gate segments 111a, 111b, and 111c are disposed adjacent to the contact 120. The gate segment 110d and dummy gate segments 111a, 111b, and 111c and the contact 120 can be separated by dielectric material filled therebetween.

In some embodiments, the conductive via VDR can be disposed on the contact 120. The conductive via VDR can taper toward the contact 120. The conductive via VDR can be covered by the dielectric material. In some embodiments, the conductive via VDR can penetrate the dielectric material disposed on the contact 120 and connect thereto. The conductive via VDR can be exposed by the dielectric material to connect to the conductive segment 133.

In some embodiments, the conductive segment 133 can be disposed on the contact 120. The conductive segment 133 can be connected to the contact 120 through the conductive via VDR. The conductive segment 160 can be disposed on the conductive segment 133. In some embodiments, the conductive segment 160 may extend along the Y-axis. The conductive via V0 can be disposed between the conductive segment 160 and the conductive segment 133. The conductive segment 160 can be connected to the conductive segment 133 through the conductive via V0.

FIG. 1C is a cross-section of a semiconductor device 10 along line 1C-1C of FIG. 1A, in accordance with some embodiments of the present disclosure. Referring to FIG. 1C, the conductive via VDR can be connected to the conductive segment 133.

In some embodiments, the backside conductive segment 180 can be disposed on the bottom surface 100b of the substrate 100. In some embodiments, the dielectric material can be disposed on the bottom surface 100b of the substrate 100 and cover the backside conductive segment 180. In some embodiments, the backside conductive segment 180 can be laterally covered by the dielectric material. The backside conductive segment 180 can be connected to the FTV 170.

In some embodiments, the power rails 141 and 142 and the conductive segments 131, 132, 133, 134, and 135 (the conductive segments 131, 132, 134, and 135 shown the track thereof only) are disposed on the top surface 100t of the substrate 100. The power rails 141 and 142 and the conductive segments 131, 132, 133, 134, and 135 may be located in the same layer. The power rails 141 and 142 and the conductive segments 131, 132, 133, 134, and 135 can extend along the X-axis. The power rails 141 and 142 and the conductive segment 133 can be separated by dielectric material filled therebetween.

FIG. 2 is a schematic layout diagram 20L of a semiconductor device 20, in accordance with some embodiments of the present disclosure. Referring to FIG. 2, the semiconductor device 20 includes a substrate 200, seven dummy gate segments 211, 212, 213, 214, 215, 216, and 217, a contact 220, a conductive via VDR, eight conductive vias VD1, VD2, VD3, VD4, VD5, VD6, VD7, and VD8, five conductive segments 231, 232, 233, 234, and 235, two power rails 241 and 242, three conductive via VOa, VOb, and VOc, and a conductive segment 260. The semiconductor device 20 may include a power cell 201. The power cell 201 may include a feed through via (FTV) penetrating the substrate 200 and electrically connected the conductive traces on the opposite sides on the substrate 200. Details of the FTV are discussed in FIGS. 2B, 2C, and 2D.

The substrate 200 can be similar to the substrate 100 in FIG. 1, and thus details thereof are not repeated here. In some embodiments, the dummy gate segments 211, 212, 213, 214, 215, 216, and 217 can be disposed on the substrate 200 and extend vertically from a top view. The dummy gate segments 211, 212, 213, 214, 215, 216, and 217 may be distributed evenly. The dummy gate segments 211, 212, 213, 214, 215, 216, and 217 may be disposed on the active regions (OD) of the substrate 200. In some embodiments, the number of dummy gate segments 211 to 217 can be more or less than seven according to need. The type (gate segment or dummy gate segment) of the segments may be determined according to need. In some embodiments, the dummy gate segments 211, 212, 213, 214, 215, 216, and 217 may be formed of an insulation material.

The contact 220 can be disposed on the substrate 200. In some embodiments, the contact 220 may be disposed adjacent to the dummy gate segments 213, 214, and 215. In some embodiments, the contact 220 is located in a layer identical to that of the dummy gate segments 213, 214, and 215. The contact 220 may be across at least one of the dummy gate segments 213, 214, and 215. In some embodiments, the contact 220 can be across three dummy gate segments 213, 214, and 215. In some embodiments, the contact 220 can be connected to the FTV (scc FIGS. 2B, 2C, and 2D). The contact 220 may be formed of conductive materials, such as copper, tungsten, aluminum, titanium, tantalum, alloys thereof, or the like.

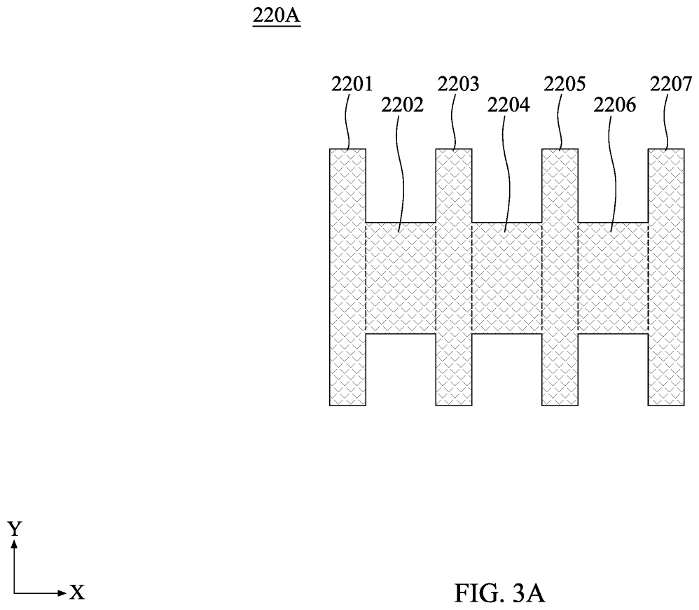

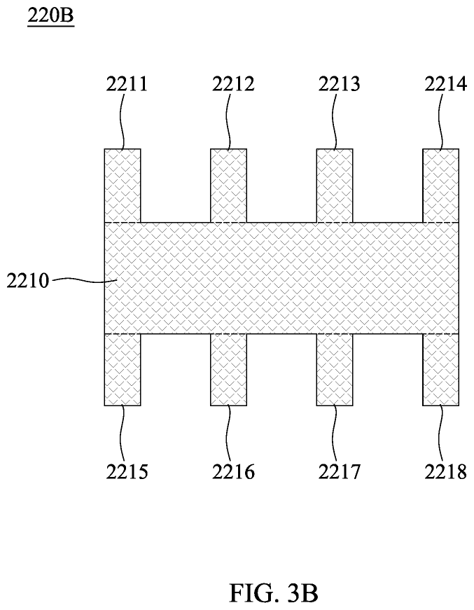

The contact 220 may be a predetermined pattern. In some embodiments, the contact 220 may have a body part and one or more protruding parts extending from the body part. For example, the contact 220 may be forked. In another embodiment, the contact 220 may be H-shaped. Details of the shape of the contact 220 are discussed in FIGS. 3A and 3B.

In some embodiments, the dummy gate segments 213, 214, and 215 shown in FIG. 2 extending through the contact 220 indicate the track of the dummy gate segments 213, 214, and 215. In the physical structure, the contact 220 does not overlap the dummy gate segments 213, 214, and 215 in a top view, since the dummy gate segments 213, 214, and 215 are partially removed to dispose the contact 220.

Referring to FIG. 2, the semiconductor device 20 can include five conductive segments 231, 232, 233, 234, and 235. The conductive segments 231, 232, 233, 234, and 235 are disposed on the dummy gate segments 211 to 217. The conductive segments 231, 232, 233, 234, and 235 are disposed on the contact 220. The contact 220 can overlap the conductive segments 231, 232, 233, 234, and 235 in a top view. In some embodiments, the conductive segments 231, 232, 233, 234, and 235 can be disposed on the active regions of the substrate 200. The conductive segments 231, 232, 233, 234, and 235 can extend perpendicular to the dummy gate segments 211 to 217. That is, the conductive segments 231, 232, 233, 234, and 235 can extend horizontally from a top view. The conductive segments 231, 232, 233, 234, and 235 can be similar to the conductive segments 131, 132, 133, 134, and 135 in FIG. 1, and thus the details thereof are not repeated here.

The power rails 241 and 242 are arranged in the same layer as the conductive segments 231, 232, 233, 234, and 235. The power rails 241 and 242 can be similar to the power rails 141 and 142 in FIG. 1, and thus the details thereof are not repeated here.

In some embodiments, a conductive via VDR can be disposed on the contact 220. For example, the conductive via VDR can be disposed on the center of the contact 220. The conductive via VDR may be disposed between the contact 220 and the conductive segment 233. The conductive via VDR can electrically connect the contact 220 and the conductive segment 233. The conductive via VDR can be smaller than contact 220. For example, the length and width of the conductive via VDR can be less than the length and width of the contact 220. In other words, the conductive via VDR can be completely within the contact 220. In some embodiments, the conductive via VDR may be larger than other normal conductive via (such as the conductive vias VD1 to VD8) in the same layer to transmit power supply signals with relative lower resistance. The width of the conductive via VDR can be greater than that of the conductive segment 233 in the vertical orientation. The conductive via VDR can be across the dummy gate segments 213, 214, and 215. The conductive via VDR may be formed of conductive materials, such as copper, tungsten, aluminum, titanium, tantalum, alloys thereof, or the like.

In some embodiments, the conductive vias VD1, VD2, VD3, VD4, VD5, VD6, VD7, and VD8 can be disposed in a layer substantially identical to that of the conductive via VDR. The conductive vias VD1 to VD8 can be disposed on the contact 220. For example, the conductive via VDR can be disposed adjacent to an edge of the contact 220. In some embodiments, the contact 220 is forked, with conductive vias VD1 to VD8 located on the tines thereof.

The conductive vias VD1 to VD4 can be disposed between the contact 220 and the conductive segment 231. The conductive vias VD1 to VD4 can overlap the conductive segment 231 from a top view. In some embodiments, the conductive vias VD1 to VD4 can electrically connect the contact 220 and the conductive segment 231. The conductive vias VD5 to VD8 can be disposed between the contact 220 and the conductive segment 235. The conductive vias VD5 to VD8 can overlap the conductive segment 235 from a top view. In some embodiments, the conductive vias VD5 to VD8 can electrically connect the contact 220 and the conductive segment 235.

In some embodiments, the size of the conductive via VDR can be greater than the size of the conductive vias VD1 to VD8. The size may be referred to as length, width, or area. In some embodiments, the conductive vias VD1 to VD8 can be conductive pillars. The conductive vias VD1 to VD8 may be formed of conductive materials, such as copper, tungsten, aluminum, titanium, tantalum, alloys thereof, or the like.

In some embodiments, the conductive segment 260 can be disposed on the conductive segments 231, 232, 233, 234, and 235. The conductive segment 260 is disposed between the dummy gate segments 211 and 212. The conductive segment 260 can extend parallel to the dummy gate segments 211 to 217. That is, the conductive segment 260 can extend vertically from a top view. In some embodiments, the conductive segments 260 and the conductive segments 231, 232, 233, 234, and 235 can overlap from a top view. The conductive segment 260 may extend beyond the power cell 201 so as to connect to other cells. The conductive segment 260 may be formed of conductive materials, such as copper, tungsten, aluminum, titanium, tantalum, alloys thereof, or the like.

In some embodiments, three conductive vias VOa, VOb, and VOc can be disposed under the conductive segment 260. The conductive via VOa may be disposed between the conductive segments 231 and 260. The conductive via VOa can electrically connect the conductive segments 231 and 260. In some embodiments, the conductive via V0 can overlap the conductive segments 231 and 260 from a top view. The conductive via VOb may be disposed between the conductive segments 233 and 260. The conductive via VOb can electrically connect the conductive segments 233 and 260. In some embodiments, the conductive via V0 can overlap the conductive segments 233 and 260 from a top view. The conductive via VOc may be disposed between the conductive segments 235 and 260. The conductive via VOc can electrically connect the conductive segments 235 and 260. In some embodiments, the conductive via V0 can overlap the conductive segments 235 and 260 from a top view.

With special patterned contact 220, the conductive segment 260 can be electrically connected to the contact 220 (or the FTV) through the conductive segments 231, 233, and 235. That is, three conductive paths can be established between the conductive segment 260 and the contact 220, and thus resistance of the conductive path can be reduced by the parallel arrangement. In addition, the special patterned contact 220 can also be utilized for routing connection.

FIG. 2A is a top view of a semiconductor device, in accordance with some embodiments of the present disclosure. FIG. 2A is a top view of a semiconductor device 20, manufactured in accordance the schematic layout diagram of FIG. 2. Some shapes shown in the layout diagram 20L will not exist in the semiconductor device 20. For example, the semiconductor device 20 may not include the cell boundary of the power cell 201 and the tracks of the conductive segments 232 and 234. In some embodiments, the conductive vias VOa to VOc are not shown in FIG. 2A since they are covered by the conductive segment 260. Similarly, the conductive vias VD1 to VD4 are not shown in FIG. 2A since they are covered by the conductive segment 231, and the conductive vias VD5 to VD8 are not shown in FIG. 2A since they are covered by the conductive segment 235. In some embodiments, the semiconductor device 20 may merely include the conductive segments 231, 233, and 235, and there may be no conductive material formed in the track of the conductive segments 232 and 234. In another embodiments, the semiconductor device 10 may include the conductive segments 231, 233, and 235, and a part of the conductive segments 232 and 234 (not shown).

FIG. 2B is a cross-section of a semiconductor device 20 along line 2B-2B of FIG. 2A, in accordance with some embodiments of the present disclosure. Referring to FIG. 2B, the substrate 200 may have a top surface 200t and a bottom surface 200b. In some embodiments, the FTV 270 may penetrate the substrate 200. The FTV 270 may taper from the bottom surface 200b to the top surface 200t (not shown). In another embodiment, the FTV 270 may taper from the top surface 200t to the bottom surface 200b (not shown). In some embodiments, the FTV 270 may have a substantially uniform width or diameter. The FTV may be rectangular or rounded from a top view. The FTV 270 may be a conductive pillar. The FTV 270 may be formed of conductive materials, such as copper, tungsten, aluminum, titanium, tantalum, alloys thereof, or the like.

In some embodiments, one or more backside conductive segments 280 can be disposed on the bottom surface 200b of the substrate 200. The backside conductive segments 280 can be patterned. In some embodiments, the backside conductive segments 280 may extend parallel to the conductive segments 231, 232, 233, 234, and 235. The backside conductive segments 280 may be formed of conductive materials, such as copper, tungsten, aluminum, titanium, tantalum, alloys thereof, or the like. The contact 220 can be disposed on the top surface 200t of the substrate 200. The contact 220 can be connected to the FTV 270. The contact 220 is wider than FTV 270. In some embodiments, the contact 220 and the backside conductive segment 280 are disposed on opposite surfaces of the substrate 200 and connected through the FTV 270.

The dummy gate segments 211, 212, 216, and 217 are disposed on the top surface 200t of the substrate 200. The dummy gate segments 211 and 217 can be disposed adjacent to opposite edges of the substrate 200. In some embodiments, the dummy gate segments 212 and 216 can be disposed adjacent to the contact 220. The dummy gate segments 211, 212, 216, and 217 and the contact 220 can be separated by dielectric material 220d filled therebetween.

In some embodiments, the conductive via VDR can be disposed on the contact 220. The conductive via VDR can taper toward the contact 220. The conductive via VDR can be covered by the dielectric material 221d. In some embodiments, the conductive via VDR can penetrate the dielectric material 221d disposed on the contact 220 and connect to the contact 220. The conductive via VDR can be exposed by the dielectric material 221d to connect to the conductive segment 233.

In some embodiments, the conductive segment 233 can be disposed on the contact 220. The conductive segment 233 can be connected to the contact 220 through the conductive via VDR. The conductive segment 260 can be disposed on the conductive segment 233. In some embodiments, the conductive segment 260 may extend along the Y-axis. The conductive via VOb can be disposed between the conductive segment 260 and the conductive segment 233. The conductive segment 260 can be connected to the conductive segment 233 through the conductive via VOb. The conductive segment 260 and the conductive via VOb can be covered by a dielectric material (not shown).

FIG. 2C is a cross-section of a semiconductor device 20 along line 2C-2C of FIG. 2A, in accordance with some embodiments of the present disclosure. Referring to FIG. 2C, the contact 220 can include four fingers disposed on the top surface 200t of the substrate 200 and separated by the dielectric material 220d. In some embodiments, each finger of the contact 220 can be connected to the conductive segment 231 through a respective conductive via VD1, VD2, VD3, or VD4.

The conductive vias VD1, VD2, VD3, and VD4 can be covered by the dielectric material 221d. In some embodiments, the conductive vias VD1, VD2, VD3, and VD4 can be embedded in the dielectric material 221d. The top surfaces of the conductive vias VD1, VD2, VD3, and VD4 can be exposed by the dielectric material 221d and connected to the conductive segment 231.

In some embodiments, the conductive segment 231 can be disposed on the contact 220. The conductive segment 231 can be connected to the contact 220 through the conductive vias VD1, VD2, VD3, and VD4. The conductive segment 260 can be disposed on the conductive segment 231. In some embodiments, the conductive segment 260 may extend along the Y-axis. The conductive via V0a can be disposed between the conductive segment 260 and the conductive segment 231. The conductive segment 260 can be connected to the conductive segment 231 through the conductive via V0a. The conductive segment 260 and the conductive via V0a can be covered by a dielectric material (not shown). With multiple conductive vias VD1, VD2, VD3, and VD4, the conductive path between the conductive segment 231 and the contact 220 can have a lower resistance.

In some embodiments, the dielectric material 280d can be disposed on the bottom surface 200b of the substrate 200. The dielectric material 280d can be disposed in a layer substantially identical to that of the backside conductive segment 280 in FIG. 2A. In some embodiments, one or more backside conductive segment 280 can be covered by the dielectric material 280d.

FIG. 2D is a cross-section of a semiconductor device 20 along line 2D-2D of FIG. 2A in accordance with some embodiments of the present disclosure. Referring to FIG. 2D, the contact 220 can be connected to the conductive segments 231, 233, and 235 through the conductive vias VD2, VDR, and VD6, respectively.

In some embodiments, the backside conductive segment 280 can be disposed on the bottom surface 200b of the substrate 200. In some embodiments, the dielectric material 280d can be disposed on the bottom surface 200b of the substrate 200 and cover the backside conductive segment 280. In some embodiments, the backside conductive segment 280 can be laterally covered by the dielectric material 280d. The backside conductive segment 280 can be connected to the FTV 270.

In some embodiments, the power rails 241 and 242 and the conductive segments 231, 232, 233, 234, and 235 (the conductive segments 232 and 234 shown the track thereof only) are disposed on the top surface 200t of the substrate 200. The power rails 241 and 242 and the conductive segments 231, 232, 233, 234, and 235 are located in the same layer. The power rails 241 and 242 and the conductive segments 231, 232, 233, 234, and 235 can extend along the X-axis. The power rails 241 and 242 and the conductive segments 231, 233, and 235 can be separated by dielectric material 230d filled therebetween.

The conductive via VDR can connect the contact 220 to the conductive segment 233. In some embodiments, the conductive via VDR may partially connect to the conductive segment 232 and/or 234 (if they exist). In some embodiments, the conductive segments 232 and 234 can be free from electrical connection with the FTV 270. In some embodiments, the conductive via VD2 can be disposed on the contact 220. The conductive via VD2 may be disposed on a finger of the contact 220. The conductive via VD2 can connect the contact 220 to the conductive segment 231. In some embodiments, the conductive via VD6 can be disposed on the contact 220. The conductive via VD6 may be disposed on a finger of the contact 220. The conductive via VD6 can connect the contact 220 to the conductive segment 235. In some embodiments, the contact 220 can be connected to the conductive segments 231, 233, and 235.

In some embodiments, the width of the conductive via VDR can be greater than the width of the conductive vias VD2 and VD6. In some embodiments, the conductive vias VD2 and VD6 can have the same size, such as width or diameter.

FIG. 3A is a top view of a contact 220A of a semiconductor device, in accordance with some embodiments of the present disclosure. Referring to FIG. 3A, the contact 220A can be similar to the contact 220 in FIGS. 2 and 2A-2D, except that the contact 220A includes seven portions 2201, 2202, 2203, 2204, 2205, 2206, and 2207. Although edges/boundaries depicted in FIG. 3A between adjacent portions, it can be understood that these edges/boundaries are shown for illustrative purpose, and may not exist in the contact 220A manufactured. The contact 220A can be formed in a single process. The portions 2201, 2202, 2203, 2204, 2205, 2206, and 2207 can be formed in a single process.

In some embodiments, the portions 2201, 2203, 2205, and 2207 can be disposed between two adjacent dummy gate segments. Referring back to FIG. 2, the portion 2201 can be disposed between the dummy gate segments 212 and 213. The portion 2203 can be disposed between the dummy gate segments 213 and 214. The portion 2205 can be disposed between the dummy gate segments 214 and 215. The portion 2207 can be disposed between the dummy gate segments 215 and 216. In some embodiments, the portions 2201, 2203, 2205, and 2207 can extend vertically, i.e., along the Y-axis.

In some embodiments, the portions 2202, 2204, 2206 can be across one dummy gate segment. Referring back to FIG. 2, the portion 2202 can be across the dummy gate segment 213. The portion 2204 can be across the dummy gate segment 214. The portion 2206 can be across the dummy gate segment 215. In some embodiments, the portions 2202, 2204, 2206 can extend vertically, i.e., along the Y-axis.

In some embodiments, the portions 2201, 2203, 2205, and 2207 (the distance in the vertical orientation) can be longer than portions 2202, 2204, and 2206. The portions 2201, 2203, 2205, and 2207 (the distance in the horizontal orientation) can be shorter than portions 2202, 2204, and 2206.

In some embodiments, the portion 2201 can be connected to the conductive segments 231 and 235 through the conductive vias VD1 and VD5, respectively. The portion 2203 can be connected to the conductive segments 231 and 235 through the conductive vias VD2 and VD6, respectively. The portion 2205 can be connected to the conductive segments 231 and 235 through the conductive vias VD3 and VD7, respectively. The portion 2207 can be connected to the conductive segments 231 and 235 through the conductive vias VD4 and VD8, respectively. In some embodiments, the portion 2202 can connect the portion 2201 and 2203. The portion 2204 can connect the portion 2203 and 2205. The portion 2206 can connect the portion 2205 and 2207.

The special patterned contact 220A having the portions 2201 to 2207 provides more landing area for the conductive vias. Therefore, the contact 220 can be connected to the conductive segment 260 through eight conductive vias VD1 to VD8 and a large size conductive via VDR, such that the resistance between the contact 220 and the conductive segment 260 can be reduced. In addition, having the portions 2201 to 2207, the contact 220 can provide more routing resources for connection.

FIG. 3B is a top view of a contact 220B of a semiconductor device, in accordance with some embodiments of the present disclosure. Referring to FIG. 3B, the contact 220B can be similar to the contact 220 in FIGS. 2 and 2A-2D, except that the contact 220A includes a body portion 2210 and eight finger portions 2211, 2212, 2213, 2214, 2215, 2216, 2217, and 2218. Although edges/boundaries depicted in FIG. 3B between adjacent portions, it can be understood that these edges/boundaries are shown for illustrative purpose, and may not exist in the contact 220B manufactured. The contact 220B can be formed in a single process. The body portion 2210 and the finger portions 2211, 2212, 2213, 2214, 2215, 2216, 2217, and 2218 can be formed in a single process.

In some embodiments, the body portion 2210 can be rectangular from a top view. The body portion 2210 can extend perpendicular to the dummy gate segments 211 to 217. The body portion 2210 can be across the dummy gate segments 213, 214, and 215. The body portion 2210 can be connected to the FTV 270 (as shown in FIG. 2B). In some embodiments, the body portion 2210 can be connected to the conductive via VDR (as shown in FIG. 2B). In some embodiments, the body portion 2210 can have a size conformal to the conductive via VDR (see FIG. 2).

In some embodiments, a side of the body portion 2210 can be connected to a side of the finger portions 2211 to 2218. The finger portions 2211, 2212, 2213, 2214, 2215, 2216, 2217, and 2218 can protrude from an edge of the body portion 2210. For example, the finger portions 2211, 2212, 2213, and 2214 can protrude from the top edge of the body portion 2210, and the finger portions 2215, 2216, 2217, and 2218 can protrude from the bottom edge of the body portion 2210.

In some embodiments, the finger portions 2211, 2212, 2213, 2214, 2215, 2216, 2217, and 2218 can be disposed between two adjacent dummy gate segments. Referring back to FIG. 2, the finger portions 2211 and 2215 can be disposed between the dummy gate segments 212 and 213. The finger portions 2212 and 2216 can be disposed between the dummy gate segments 213 and 214. The finger portions 2213 and 2217 can be disposed between the dummy gate segments 214 and 215. The finger portions 2214 and 2218 can be disposed between the dummy gate segments 215 and 216. The finger portions 2211, 2212, 2213, 2214, 2215, 2216, 2217, and 2218 can extend perpendicular to the body portion 2210. In some embodiments, the finger portions 2211, 2212, 2213, 2214, 2215, 2216, 2217, and 2218 can extend vertically, i.e., along the Y-axis. The width of the finger portions 2211, 2212, 2213, 2214, 2215, 2216, 2217, and 2218 (the distance in the horizontal orientation) can be less than that of the body portion 2210.

In some embodiments, a left side of the body portion 2210 can be aligned with a side of the finger portion 2211. The lateral surface of the body portion 2210 can be aligned with that of the finger portion 2211. In some embodiments, the left side of the body portion 2210 can be aligned with a side of the finger portion 2215. The lateral surface of the body portion 2210 can be aligned with that of the finger portion 2215. In some embodiments, a right side of the body portion 2210 can be aligned with a side of the finger portion 2214. The lateral surface of the body portion 2210 can be aligned with that of the finger portion 2214. In some embodiments, the right side of the body portion 2210 can be aligned with a side of the finger portion 2218. The lateral surface of the body portion 2210 can be aligned with that of the finger portion 2215. In some embodiments, the finger portion 2211 can be connected to conductive segment 231 through the conductive via VD1. The finger portion 2212 can be connected to conductive segment 231 through the conductive via VD2. The finger portion 2213 can be connected to conductive segment 231 through the conductive via VD3. The finger portion 2214 can be connected to conductive segment 231 through the conductive via VD4.

The finger portion 2215 can be connected to conductive segment 235 through the conductive via VD5. The finger portion 2216 can be connected to conductive segment 235 through the conductive via VD6. The finger portion 2217 can be connected to conductive segment 235 through the conductive via VD7. The finger portion 2218 can be connected to conductive segment 235 through the conductive via VD8.

The special patterned contact 220B having the body portion 2210 and finger portions 2211 to 2218 provides more landing area for the conductive vias. Therefore, the contact 220 can be connected to the conductive segment 260 through eight conductive vias VD1 to VD8 and a large size conductive via VDR, such that the resistance between the contact 220 and the conductive segment 260 can be reduced. In addition, having the body portion 2210 and finger portions 2211 to 2218, the contact 220 can provide more routing resources for connection.

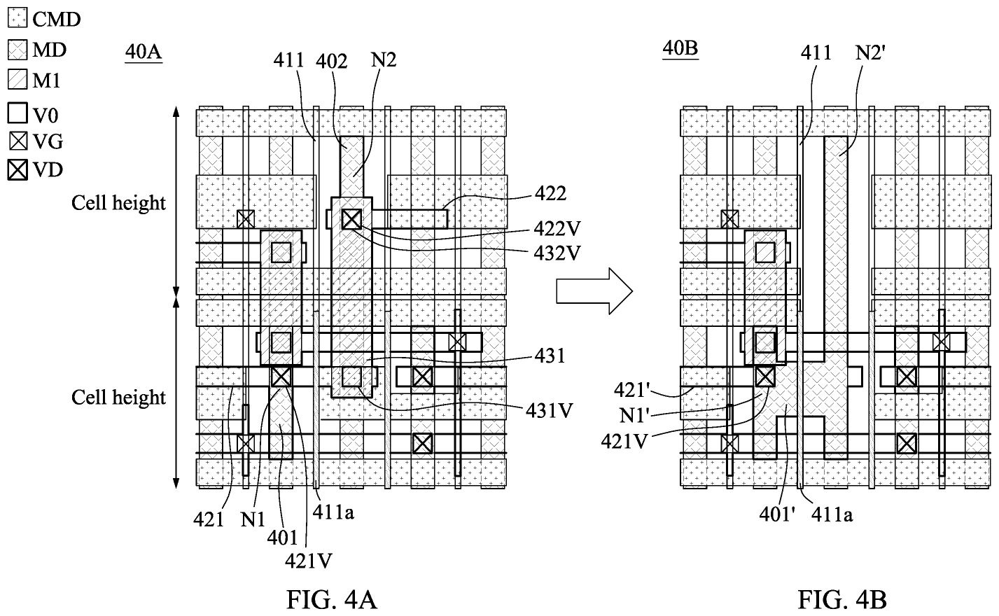

FIG. 4A is a schematic layout diagram of a semiconductor device 40A, in accordance with some embodiments of the present disclosure.

The semiconductor device 40A can include a substrate (not shown) similar to the substrate 100 of FIG. 1. Referring to FIG. 4A, the semiconductor device 40A can include one or more gate segments (PO) (such as 411) extending vertically, one or more source/drain contacts (MD) (such as 401 and 402) interposed between the gate segments, one or more isolation structure (CMD) extending horizontally, one or more gate conductive vias (VG) disposed on the gate segments, one or more source/drain conductive vias (VD) disposed on the source/drain contacts (MD), one or more first conductive segments (M0) extending horizontally, one or more first conductive vias (V0) disposed on the first conductive segments (M0), and one or more second conductive segments (M1) extending vertically.

In some embodiments, the gate segments (PO), the source/drain contacts (MD), and the isolation structure (CMD) can be disposed on the substrate and in the same layer. In some embodiments, the isolation structure (CMD) may be formed of an insulation material. In some embodiments, the source/drain contacts (such as source/drain contacts 401 and 402) of the semiconductor device 40A can be cut into several segments by the isolation structure (CMD). The gate conductive vias (VG) can be disposed between the gate segments (PO) and the first conductive segments (M0). The conductive vias (VG) can connect the gate segments (PO) and the first conductive segments (M0). The source/drain conductive vias (VD) can be disposed between the source/drain contacts (MD) and the first conductive segments (M0). The source/drain conductive vias (VD) can connect the source/drain contacts (MD) and the first conductive segments (M0). In some embodiments, the gate conductive vias (VG) and source/drain conductive vias (VD) are in the same layer.

The first conductive segments (M0) can be patterned. In some embodiments, the first conductive segments (M0) can extend perpendicular to the gate segments (PO) and the source/drain contacts (MD).

The second conductive segments (M1) can be patterned. In some embodiments, the second conductive segments (M1) can extend perpendicular to the first conductive segments (M0). In some embodiments, the second conductive segments (M1) can be connected to the first conductive segments (M0) through the first conductive vias (V0).

Referring to FIG. 4A, the semiconductor device 40A includes source/drain contacts (MD) 401 and 402, a gate segment 411, a dummy gate segment 411a, conductive via (VD) 421V and 422V, conductive segments (M0) 421 and 422, conductive via (V0) 431V and 432V, and conductive segment (M1) 431. The semiconductor device 40A can include a conductive path established between two nodes N1 and N2.

In some embodiments, the source/drain contact 401 can be connected to the conductive segment (M0) 421 through the conductive via (VD) 421V. That is, the conductive via (VD) 421V can be disposed between the source/drain contact 401 and the conductive segment 421. The conductive segment 421 may extend horizontally and across the dummy gate segment 411a. In some embodiments, the dummy gate segment 411a and the gate segment 411 can be disposed on the same track. The dummy gate segment 411a and the gate segment 411 can be aligned. In some embodiments, the conductive via (V0) 431V can be disposed on and connected to the conductive segment 421. In some embodiments, the conductive via 431V and the conductive via 421V can be disposed on the opposite sides of the conductive segment 421. The conductive via 431V can be disposed on the source/drain contact 402. In other words, the conductive via 431V and the conductive via 421V can be disposed on the opposite sides of the dummy gate segment 411a.

In some embodiments, the upper source/drain contact 402 can be connected to the conductive segment (M0) 422 through the conductive via (VD) 422V. That is, the conductive via (VD) 422V can be disposed between the source/drain contact 402 and the conductive segment 422. The conductive segment 421 may extend horizontally and across one or more gate segments. In some embodiments, the conductive via (V0) 432V can be disposed directly on the conductive via (VD) 422V. In some embodiments, the conductive segment (M0) 422 can be disposed between the conductive via (V0) 432V and the conductive via (VD) 422V. The conductive via (V0) 432V overlaps the conductive via (VD) 422V (scc FIG. 4A).

In some embodiments, the conductive segment (M1) 431 can be disposed on the conductive vias 431V and 432V. The conductive segment 431 can electrically connect the conductive vias 431V and 432V. That is, the source/drain contact 401 can be electrically connected to the source/drain contact 402 through the conductive via 421V, conductive segment 421, conductive via 431V, conductive segment 431, conductive via 432V, conductive segment 422, and conductive via 422V, which may be referred to as the conductive path between the nodes N1 and N2. In such a case, the conductive path between the nodes N1 and N2 may utilize at least two levels of conductive segments for routing.

FIG. 4B is a schematic layout diagram of a semiconductor device 40B, in accordance with some embodiments of the present disclosure. The semiconductor device 40B of FIG. 4B releases the routing resource of the semiconductor device 40A of FIG. 4A by using patterned source/drain contact.

Referring to FIG. 4B, the semiconductor device 40B includes a patterned source/drain contacts (MD) 401′, a gate segment 411, a dummy gate segment 411a, a conductive via (VD) 421V, and a conductive segment (M0) 421′. The semiconductor device 40B can include a conductive path established between two nodes N1′ and N2′. The semiconductor device 40B is similar to the semiconductor device 40A in FIG. 4A, except that the semiconductor device 40B includes a patterned source/drain contact (MD) 401′.

In some embodiments, the patterned source/drain contact 401′ can be over the dummy gate segment 411a, and thus the two source/drain contacts on the opposite sides of the dummy gate segment 411a can be connected. The conductive path between N1′ and N2′ can be implemented by the patterned source/drain contact 401′. In such a case, the routing resource (such as the conductive segments and conductive vias on the patterned source/drain contact 401′) can be released for other connection. In addition, using the patterned source/drain contact 401′ to connect nodes N1′ and N2′ can also reduce the parasitic capacitance and resistance of the conductive segments/vias.

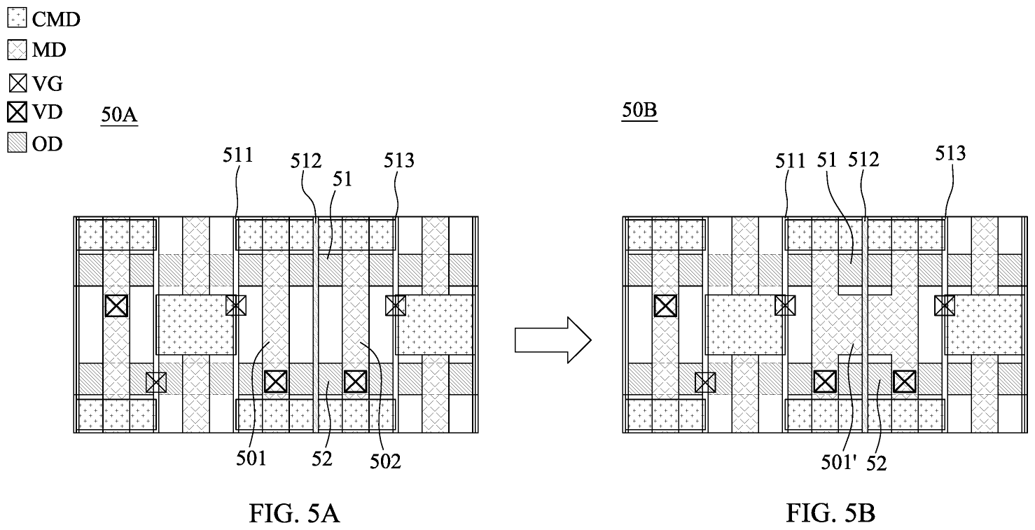

FIG. 5A is a schematic layout diagram of a semiconductor device 50A, in accordance with some embodiments of the present disclosure.

The semiconductor device 50A can include a substrate (not shown) similar to the substrate 100 of FIG. 1. Referring to FIG. 5A, the semiconductor device 50A can include one or more active regions (OD) extending horizontally, one or more gate segments (PO) (such as 511 and 513) disposed on the active regions (OD) and extending vertically, one or more source/drain contacts (MD) (such as 501 and 502) interposed between the gate segments, one or more isolation structure (CMD) extending horizontally, one or more gate conductive vias (VG) disposed on the gate segments (PO), and one or more source/drain conductive vias (VD) disposed on the source/drain contacts (MD).

The active regions (OD) of the semiconductor device 50A may refer to the active regions (OD) of the semiconductor device 10 of FIG. 1, and thus the details are omitted for clarity.

In some embodiments, the gate segments (PO), the source/drain contacts (MD), and the isolation structure (CMD) can be disposed on the substrate and in the same layer. In some embodiments, the isolation structure (CMD) may be formed of an insulation material. In some embodiments, the source/drain contacts (such as source/drain contacts 501 and 502) of the semiconductor device 50A can be cut into several segments by the isolation structure (CMD).

The gate conductive vias (VG) can be disposed on the gate segments (PO) for electrical connection (routing). The source/drain conductive vias (VD) can be disposed on the source/drain contacts (MD) for electrical connection (routing). In some embodiments, the gate conductive vias (VG) and source/drain conductive vias (VD) are in the same layer.

Referring to FIG. 5A, the semiconductor device 50A includes active regions 51 and 52, source/drain contacts (MD) 501 and 502, gate segments 511 and 513, and a dummy gate segment 512.

In some embodiments, the active regions 51 and 52 can extend horizontally. The gate segments 511 and 513 can be disposed on the active regions 51 and 52. The active regions 51 and 53 may include source/drain regions and a channel region of a transistor (not shown) interposed between the two source/drain regions. In some embodiments, gate segments 511 and 513 may be disposed on the channel region to form the gate of a transistor.

The dummy gate segment 512 can be disposed between the gate segments 511 and 513. In some embodiments, the dummy gate segment 512 can be disposed on the active regions 51 and 52. Adding the dummy gate segment 512 can connect the active regions 51 and 52 on the opposite sides of the dummy gate segment 512, such that the source/drain area between the gate segments 511 and 513 can be enlarged. Therefore, the transistor speed can be improved.

FIG. 5B is a schematic layout diagram of a semiconductor device 50B, in accordance with some embodiments of the present disclosure. Compared to the semiconductor device 50A of FIG. 5A, the semiconductor device 50B of FIG. 5B reduce the resistance and enhance the speed by using patterned source/drain contact.

Referring to FIG. 5B, the semiconductor device 50B includes active regions 51 and 52, a patterned source/drain contact (MD) 501′, gate segments 511 and 513, and a dummy gate segment 512. The semiconductor device 50B is similar to the semiconductor device 50A in FIG. 5A, except that the semiconductor device 50B includes a patterned source/drain contact (MD) 501′.

In some embodiments, the patterned source/drain contact 501′ can be over the dummy gate segment 512, and thus the two source/drain contacts (i.e., the source/drain contacts 501 and 502 in FIG. 5A) on the opposite sides of the dummy gate segment 512 can be connected. In such a case, the resistance of the semiconductor device 50B can be reduced. In the same time, the performance (operating rate) of the semiconductor device 50B can be enhanced with the connected active regions 51 and 52 and patterned source/drain contact 501′.

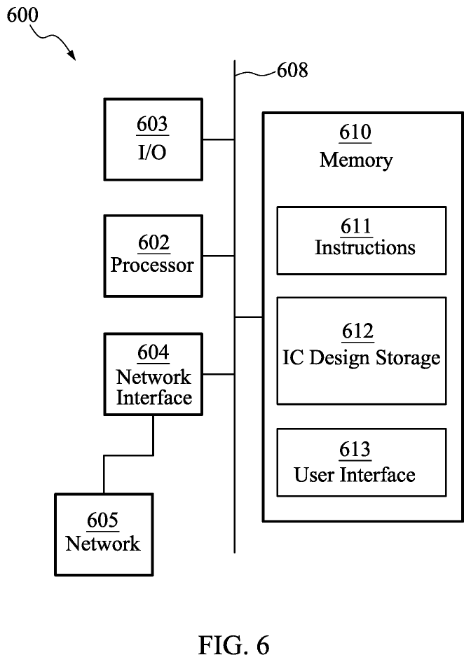

FIG. 6 is a block diagram of IC design system 600, in accordance with some embodiments. Methods described herein of designing IC layout diagrams in accordance with one or more embodiments are implementable, for example, using IC design system 600, in accordance with some embodiments. In some embodiments, IC design system 600 can be an APR system, can include an APR system, or can be a part of an APR system, usable for performing an APR method.

In some embodiments, IC design system 600 includes a processor 602 and non-transitory, computer-readable memory 610. Memory 610, amongst other things, is encoded with, i.e., stores, computer program code, i.e., a set of executable instructions 611. Execution of instructions 611 by the processor 602 represents (at least in part) an EDA tool which implements a portion or all of a method, e.g., a method of generating an IC layout diagram described above (hereinafter, the noted processes and/or methods).

Processor 602 is electrically coupled to computer-readable memory 610 via a bus 608. Processor 602 is also electrically coupled to an I/O interface 603 by bus 608. Network interface 604 is also electrically connected to processor 602 via bus 608. Network interface 604 is connected to a network 605, so that processor 602 and computer-readable memory 610 are capable of connecting to external elements via network 605. Processor 602 is configured to execute instructions 611 encoded in computer-readable memory 610 in order to cause IC design system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, memory 610 is an electronic, magnetic, optical, electromagnetic, infrared, and/or a semiconductor system (or apparatus or device). For example, memory 610 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 610 includes a compact disk-read only memory (CD-ROM), a compact disk-read/write (CD-R/W), and/or a digital video disc (DVD).

In one or more embodiments, memory 610 stores instructions 611 configured to cause IC design system 600 (where such execution represents (at least in part) the EDA tool) to be usable for performing a portion or all of the noted processes and/or methods. In one or more embodiments, memory 610 also stores information which facilitates performing a portion or all of the noted processes and/or methods. In one or more embodiments, memory 610 includes IC design storage 612 configured to store one or more IC layout diagrams.

IC design system 600 includes I/O interface 603. I/O interface 603 is coupled to external circuitry. In one or more embodiments, I/O interface 603 includes a keyboard, keypad, mouse, trackball, trackpad, touchscreen, and/or cursor direction keys for communicating information and commands to processor 602.

IC design system 600 also includes network interface 604 coupled to processor 602. Network interface 604 allows IC design system 600 to communicate with network 605, to which one or more other computer systems are connected. Network interface 604 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC design systems 600.

IC design system 600 is configured to receive information through I/O interface 603. The information received through I/O interface 603 includes one or more of instructions, data, design rules, libraries of standard cells, and/or other parameters for processing by processor 602. The information is transferred to processor 602 via bus 608. IC design system 600 is configured to receive information related to a UI through I/O interface 603. The information is stored in memory 610 as user interface (UI) 613.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC design system 600. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

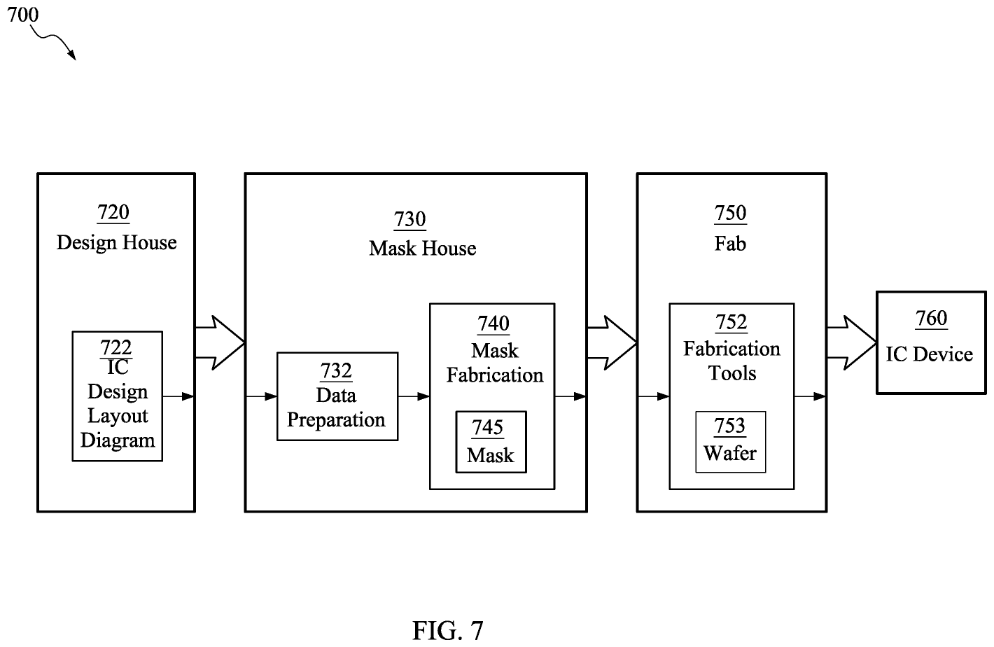

FIG. 7 is a block diagram of IC manufacturing system 700, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using IC manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. The entities in IC manufacturing system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout diagram 722. IC design layout diagram 722 includes various geometrical patterns, e.g., an IC layout diagram discussed above. The geometrical patterns correspond to patterns of metal, oxide, or semiconductor layers that make up the various components of IC device 760 to be fabricated. The various layers combine to form various IC features. For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form the IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Mask house 730 includes mask data preparation 732 and mask fabrication 744. Mask house 730 uses IC design layout diagram 722 to manufacture one or more masks 745 to be used for fabricating the various layers of IC device 760 according to IC design layout diagram 722. Mask house 730 performs mask data preparation 732, where IC design layout diagram 722 is translated into a representative data file (RDF). Mask data preparation 732 provides the RDF to mask fabrication 744. Mask fabrication 744 includes a mask writer. A mask writer converts the RDF to an image on a substrate, such as mask (reticle) 745 or a semiconductor wafer 753. The IC design layout diagram 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the description of mask data preparation 732 has been simplified for the purposes of clarity. In some embodiments, mask data preparation 732 includes additional features such as a logic operation (LOP) to modify the IC design layout diagram 722 according to manufacturing rules. Additionally, the processes applied to IC design layout diagram 722 during mask data preparation 732 may be executed in a variety of different orders.

After mask data preparation 732 and during mask fabrication 744, a mask 745 or a group of masks 745 are fabricated based on the modified IC design layout diagram 722. In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies. In some embodiments, mask 745 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask. In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC fab 750 is an IC fabrication business that includes one or more manufacturing facilities for the fabrication of a variety of different IC products. In some embodiments, IC Fab 750 is a semiconductor foundry. For example, there may be a manufacturing facility for the front-end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 750 includes (wafer) fabrication tools 752 configured to execute various manufacturing operations on semiconductor wafer 753 such that IC device 760 is fabricated in accordance with the mask(s), e.g., mask 745. In various embodiments, fabrication tools 752 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 750 uses mask(s) 745 fabricated by mask house 730 to fabricate IC device 760. Thus, IC fab 750 at least indirectly uses IC design layout diagram 722 to fabricate IC device 760. In some embodiments, semiconductor wafer 753 is fabricated by IC fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

According to some embodiments, a semiconductor device is provided. The semiconductor device comprises a substrate having a first surface and a second surface opposite to the first surface, one or more dummy gate segments disposed on the first surface of the substrate and extend in parallel, a first contact on the first surface of the substrate, a backside conductive via penetrating from the second surface to the first surface of the substrate, and connected to the first contact, a first conductive segment and a second conductive segment disposed on and extending perpendicular to the one or more dummy gate segments. The first contact across at least one of the dummy gate segments, and is connected to the first conductive segment and the second conductive segment.

According to another embodiment, a semiconductor device including a power cell is provided. The power cell includes a substrate, one or more dummy gate segments disposed on the substrate and extending in a first direction, and a first contact disposed on the substrate and adjacent to the one or more dummy gate segments. The first contact is configured to receive the power supply. The first contact includes a first portion and a second portion adjacent to the first portion, wherein the first portion extends perpendicular to the first direction and the second portion extends perpendicular to the first portion.

According to other embodiments, a semiconductor device is provided. The semiconductor device includes a substrate having a first surface and a second surface opposite to the first surface, one or more dummy gate segments disposed on the first surface of the substrate and extending in parallel, and a first contact disposed on the first surface of the substrate, and configured to receive the power supply. The first contact includes a first portion and a second portion adjacent to the first portion, wherein a width of the second portion is less than a width of the first portion.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor device, comprising:
a substrate having a first surface and a second surface opposite to the first surface;
one or more dummy gate segments disposed on the first surface of the substrate and extending in parallel;
a first contact on the first surface of the substrate, the first contact across at least one of the dummy gate segments;
a backside conductive via penetrating from the second surface to the first surface of the substrate, and connected to the first contact; and
a first conductive segment and a second conductive segment disposed on and extending perpendicular to the one or more dummy gate segments,
wherein the first contact is connected to the first conductive segment and the second conductive segment.

2. The semiconductor device of claim 1, wherein the first contact includes a first portion across a first dummy gate segment and a second portion across a second dummy gate segment.

3. The semiconductor device of claim 1, further comprising a third conductive segment adjacent to the first conductive segment and extending parallel to the first conductive segment, wherein the first contact is connected to the third conductive segment.

4. The semiconductor device of claim 1, wherein the first contact is connected to the first conductive segment through a first conductive via, and the first contact is connected to the second conductive segment through a second conductive via, and wherein a size of the first conductive via is greater than a size of the second conductive via.

5. The semiconductor device of claim 1, further comprising a fourth conductive segment disposed between the first conductive segment and the second conductive segment, wherein the fourth conductive segment is free from electrical connection with the backside conductive via.

6. The semiconductor device of claim 5, wherein the first contact overlaps the first conductive segment, the second conductive segment, and the fourth conductive segment in a top view.

7. The semiconductor device of claim 1, further comprising a backside conductive segment disposed on the second surface of the substrate and connected to the backside conductive via.

8. A semiconductor device, comprising:
a power cell, comprising:
a substrate;
one or more dummy gate segments disposed on the substrate and extending in a first direction; and
a first contact disposed on the substrate and adjacent to the one or more dummy gate segments, the first contact configured to receive the power supply,
wherein the first contact includes a first portion and a second portion adjacent to the first portion, wherein the first portion extends perpendicular to the first direction and the second portion extends perpendicular to the first portion.

9. The semiconductor device of claim 8, wherein a side of the first portion is aligned with a side of the second portion.

10. The semiconductor device of claim 8, wherein the second portion protrudes from a medium part of a side of the first portion in a top view.

11. The semiconductor device of claim 8, wherein a width of the second portion is smaller than a width of the first portion.

12. The semiconductor device of claim 8, further comprising:
a first conductive segment connected to the first portion through a first conductive via; and
a second conductive segment connected to the second portion through a second conductive via.

13. The semiconductor device of claim 12, wherein a size of the first conductive via is greater than a size of the second conductive via.

14. The semiconductor device of claim 12, wherein the first conductive via extends across at least two dummy gate segments.

15. The semiconductor device of claim 8, further comprising a backside conductive via penetrating from the substrate and connecting the first contact to the power supply.

16. A semiconductor device, comprising:
a substrate having a first surface and a second surface opposite to the first surface;
one or more dummy gate segments disposed on the first surface of the substrate and extending in parallel; and
a first contact disposed on the first surface of the substrate, and configured to receive the power supply,
wherein the first contact includes a first portion and a second portion adjacent to the first portion, wherein a width of the second portion is less than a width of the first portion.

17. The semiconductor device of claim 16, further comprising
a first conductive via disposed on the first portion of the first contact; and
a second conductive via disposed on the second portion of the first contact,
wherein a size of the second conductive via is less than a size of the first conductive via.

18. The semiconductor device of claim 17, wherein the first conductive via is across at least two dummy gate segments.

19. The semiconductor device of claim 16, wherein the first portion is across at least one dummy gate segment.

20. The semiconductor device of claim 16, further comprising a third conductive via penetrating from the second surface to the first surface of the substrate, wherein the third conductive via is connected to the first portion of the first contact.
